(19) United States
(12) Patent Application Publication
(10) Pub. No.: US 2020/0176330 A1
(43) Pub. Date: Jun. 4, 2020

(54) A STRUCTURE AND METHOD FOR COMPLEMENTARY METAL OXIDE SEMICONDUCTOR (CMOS) ISOLATION

(71) Applicant: QUALCOMM Incorporated, San Diego, CA (US)

(72) Inventor: Haining YANG, San Diego, CA (US)

(21) Appl. No.: 16/204,949

(22) Filed: Nov. 29, 2018

(51) Int. Cl. H01L 21/8238; H01L 21/762; H01L 27/092; H01L 29/06

(52) U.S. Cl. CPC H01L 21/823878; H01L 29/0649; H01L 27/092; H01L 21/76224

(57) ABSTRACT

Aspects of the disclosure are directed to isolation in integrated circuits. In accordance with one aspect, implementing a complementary metal oxide semiconductor (CMOS) isolation in an integrated circuit (IC) includes etching an interlayer dielectric (ILD) between two of a plurality of gates in a first section of an integrated circuit (IC); etching a semiconductor substrate to form a trench within an active region in the first section; and filling the trench with an insulator in the first section and planarizing the integrated circuit (IC).

### TECHNICAL FIELD

This disclosure relates generally to the field of isolation in integrated circuits, and, in particular, to complementary metal oxide semiconductor (CMOS) isolation.

### BACKGROUND

Integrated circuits (ICs) may be manufactured with billions of transistors on a single monolithic device. For example, there may be a very high spatial density of complementary metal oxide semiconductor (CMOS) transistors on the IC. In one example, a very small spacing between adjacent CMOS transistors implies very small spacing between adjacent gates. One important feature of integrated circuits with CMOS transistors is the need for electrical isolation between adjacent gates. For example, isolation techniques may be implemented on integrated circuits to minimize current leakage between adjacent semiconductor devices (e.g., CMOS transistors) of an integrated circuit. As transistor density increases and transistor feature size decreases, isolation techniques on integrated circuits become more challenging. Hence, improved techniques for CMOS electrical isolation in integrated circuits are desired.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides complementary metal oxide semiconductor (CMOS) isolation. Accordingly, a method for implementing a complementary metal oxide semiconductor (CMOS) isolation, the method including etching an interlayer dielectric (ILD) between two of a plurality of gates in a first section of an integrated circuit (IC); etching a semiconductor substrate to form a trench within an active region in the first section; and filling the trench with an insulator in the first section and planarizing the integrated circuit (IC).

In one example the method further includes forming a shallow trench isolation (STI) in the semiconductor substrate for a second section of the integrated circuit (IC). In one example, the first section is a p-type metal oxide semiconductor (PMOS) section and the second section is a n-type metal oxide semiconductor (NMOS) section. In one example, the first section is a n-type metal oxide semiconductor (NMOS) section and the second section is a p-type metal oxide semiconductor (PMOS) section.

In one example the method further includes placing the plurality of gates in the first section and in the second section of the integrated circuit (IC). In one example, the first section and the second section are adjacent. In one example the method further includes depositing an interlayer dielectric (ILD) to surround the plurality of gates in the first section and in the second section of the integrated circuit (IC) and planarizing the integrated circuit (IC).

In one example, the interlayer dielectric (ILD) is an oxide material. In one example, the planarizing includes removing excess interlayer dielectric (ILD) above the plurality of gates. In one example the method further includes forming a mask above the interlayer dielectric (ILD) in the first section and in the second section of the integrated circuit (IC) and exposing a diffusion break region.

In one example, the planarizing includes removing the mask above the interlayer dielectric (ILD) in the first section and the second section. In one example, the diffusion break region is over the first section only. In one example, the plurality of gates includes a polysilicon gate, a replacement metal gate and gate insulator. In one example, the plurality of gates is surrounded by at least one spacer.

Another aspect of the disclosure provides a method for implementing a complementary metal oxide semiconductor (CMOS) isolation, the method including etching an interlayer dielectric (ILD) between two of a plurality of gates in a first section and a second section of an integrated circuit (IC); etching a semiconductor substrate to form a first trench within a first active region in the first section and a second trench within a second active region in the second section; and filling the first trench with a first insulator in the first section and filling the second trench with a second insulator in the second section and planarizing the integrated circuit (IC).

In one example, the planarizing includes removing a mask above the interlayer dielectric (ILD) in the first section and the second section. In one example, the first section is a p-type metal oxide semiconductor (PMOS) section and the second section is a n-type metal oxide semiconductor (NMOS) section. In one example, the first section is a n-type metal oxide semiconductor (NMOS) section and the second section is a p-type metal oxide semiconductor (PMOS) section.

In one example, the plurality of gates includes a polysilicon gate, a replacement metal gate and gate insulator. In one example, the plurality of gates is surrounded by at least one spacer. In one example the method further includes forming a semiconductor substrate for the first section and the second section of the integrated circuit (IC). In one example the method further includes placing the plurality of gates in the first section and the second section of the integrated circuit (IC).

In one example the method further includes depositing the interlayer dielectric (ILD) to surround the plurality of gates in the first section and the second section of the integrated circuit (IC). In one example the method further includes forming a mask above the interlayer dielectric (ILD) in the first section and the second section of the integrated circuit (IC) and exposing a diffusion break region. In one example, the diffusion break region is over both the first section and the second section.

Another aspect of the disclosure provides an apparatus with complementary metal oxide semiconductor (CMOS) isolation, the apparatus including a semiconductor substrate; a first pair of transistors coupled to the semiconductor substrate, wherein a first of the first pair of transistors includes a first gate and a second of the first pair of transistors includes a second gate; a first insulator positioned between the first gate and the second gate, wherein the first insulator extends through the semiconductor substrate.

In one example, the apparatus further includes a second pair of transistors coupled to the semiconductor substrate, wherein a first of the second pair of transistors includes a third gate and a second of the second pair of transistors includes a fourth gate; a second insulator positioned between the third gate and the fourth gate, wherein the second insulator extends through the semiconductor substrate, and wherein the second pair of transistors is a pair of p-type metal oxide semiconductor (PMOS) transistors and the first pair of transistors is a pair of n-type metal oxide semiconductor (NMOS) transistors.

Another aspect of the disclosure provides a computer-readable medium storing computer executable code, operable on a device including at least one processor and at least one memory coupled to the at least one processor, wherein the at least one processor is configured to implement complementary metal oxide semiconductor (CMOS) isolation, the computer executable code including instructions for causing a computer to etch an interlayer dielectric (ILD) between two of a plurality of gates in a first section of an integrated circuit (IC); instructions for causing the computer to etch a semiconductor substrate to form a trench within an active region in the first section; and instructions for causing the computer to fill the trench with an insulator in the first section and to planarize the integrated circuit (IC).

In one example, the computer-readable medium further includes instructions for causing the computer to form a shallow trench isolation (STI) in the semiconductor substrate for a second section of an integrated circuit (IC). In one example, the computer-readable medium further includes instructions for causing the computer to deposit an interlayer dielectric (ILD) to surround the plurality of gates in the first section and in the second section of the integrated circuit (IC), to planarize the integrated circuit (IC), to form a mask above the interlayer dielectric (ILD) in the first section and in the second section of the integrated circuit (IC), and to expose a diffusion break region.

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates a top view of three examples of CMOS isolation techniques.

FIG. 2 illustrates a side view of the three examples of CMOS isolation techniques illustrated in FIG. 1.

FIG. 3 illustrates an example set of graphs showing the effects of tensile stress on n-type metal oxide semiconductor (NMOS) transistor and p-type metal oxide semiconductor (PMOS) transistor performance for DDB isolation.

FIG. 4 illustrates an example set of graphs showing the effects of tensile stress on n-type metal oxide semiconductor (NMOS) transistor and p-type metal oxide semiconductor (PMOS) transistor performance for SDB isolation.

FIG. 5 illustrates a first example of a between gate isolation (BGI) technique.

FIG. 6 illustrates a second example of a between gate isolation (BGI) technique.

FIG. 7 illustrates a third example of a between gate isolation (BGI) technique.

FIG. 8 illustrates a first process implementation step for BGI isolation in an integrated circuit to form a shallow trench isolation (STI) in a semiconductor substrate with etching and filling of oxide.

FIG. 9 illustrates a second process implementation step for BGI isolation in an integrated circuit to form gates and spacers.

FIG. 10 illustrates a third process implementation step for BGI isolation in an integrated circuit to deposit an interlayer dielectric (ILD) and to planarize the integrated circuit.

FIG. 11 illustrates a fourth process implementation step for BGI isolation in an integrated circuit to form a mask and to expose a diffusion break region.

FIG. 12 illustrates a fifth process implementation step for BGI isolation in an integrated circuit to etch the ILD between two gates in a PMOS section.

FIG. 13 illustrates a sixth process implementation step for BGI isolation in an integrated circuit to etch the semiconductor substrate to form a trench within an active region self-aligned to gates with spacers in PMOS section.

FIG. 14 illustrates a seventh process implementation step for BGI isolation in an integrated circuit to fill the trench with insulator in PMOS section and to planarize the integrated circuit.

FIG. 15 illustrates a first process flow for implementing between gate isolation (BGI) in an integrated circuit with a first section and a second section.

FIG. 16 illustrates a second process flow for implementing between gate isolation (BGI) in an integrated circuit with a first section and a second section.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

Integrated circuits (e.g., chips) include a plurality of semiconductor devices, such as transistors. One type of transistor is a metal oxide semiconductor (MOS) transistor. There are various examples of MOS transistors. One example of MOS transistor is a complementary metal oxide semiconductor (CMOS) transistor. CMOS transistors include both p-type metal oxide semiconductor (PMOS) transistors and n-type metal oxide semiconductor (NMOS) transistors. P-type MOS transistors have charge carriers which are predominantly positively charged (i.e., p-type), for example, holes. N-type MOS transistors have charge carriers which are predominantly negatively charged (i.e., n-type), for example, electrons. Each CMOS transistor has at least three terminals: a gate, a source and a drain. In one example, current flow in a CMOS transistor is primarily between the source and the drain. In one example, CMOS transistor current flow between the source and the drain depends on a gate voltage state. For example, if the gate voltage state is zero (e.g., with a voltage magnitude less than a threshold), the CMOS transistor current flow between the source and drain may be inactive (e.g., negligible or zero current). For example, if the gate voltage state is non-zero (e.g., with a voltage magnitude greater than a threshold), the CMOS transistor current flow between the source and drain may be active (i.e., non-negligible current). In one example, the gate is the primary control input for a CMOS transistor (i.e., CMOS transistor current flow may be controlled by the gate voltage state).

One example of CMOS electrical isolation (e.g., CMOS isolation) is a diffusion break. A diffusion break provides electrical isolation between adjacent semiconductor devices (e.g., CMOS transistors) in an integrated circuit (e.g., CMOS IC). For example, a diffusion break may occupy a location of one or more gates in a CMOS IC. A gate location occupied by a diffusion break may not be used for IC nominal operation so it may be designated as a dummy gate space. A gate which is located at a dummy gate space may be known as a dummy gate.

In one example, double diffusion break (DDB) is a CMOS isolation technique which occupies two dummy gate spaces for its implementation. For example, a dummy gate used for DDB may consist of conducting material (e.g., metal) and may be used as a local routing path. In one example, DDB isolation may be formed as an initial process step prior to gate formation. For example, DDB may be used to isolate PMOS or NMOS transistors.

In one example, single diffusion break (SDB) is a CMOS isolation technique which occupies one dummy gate space for its implementation. In one example, SDB may have a smaller footprint (e.g., 20 nm wide feature size) than a DDB footprint (e.g., 54 nm wide feature size) and thus may save chip area. However, for example, a dummy gate used for SDB may consist of an insulator and may not be used as a local routing path. In one example, SDB isolation may be formed after gate formation. For example, gate material may be removed to form a gate opening, and a semiconductor (e.g., silicon) substrate may be removed through the gate opening. For example, SDB may be used to isolate PMOS or NMOS transistors.

For example, SDB may require removal of a high dielectric constant (i.e., high-K) material and metal gate material around a shared gate with wet chemicals. In one example, a high dielectric constant material has a dielectric constant greater than that of silicon dioxide (i.e., SiO₂) and may be used to maintain gate capacitance. In one example, a low dielectric constant (i.e., low-K) material has a dielectric constant less than that of silicon dioxide (i.e., SiO₂) In one example, removal with wet chemicals may encroach into adjacent semiconductor devices which share the same gate. In one example, SDB may use a CT mask (e.g., a “gate cut” mask) to remove materials around the shared gate which may make gate contact difficult or impossible.

In one example, mixed diffusion break (MDB) is a CMOS isolation technique which employs DDB for NMOS transistors and SDB for PMOS transistors to maximize semiconductor device performance.

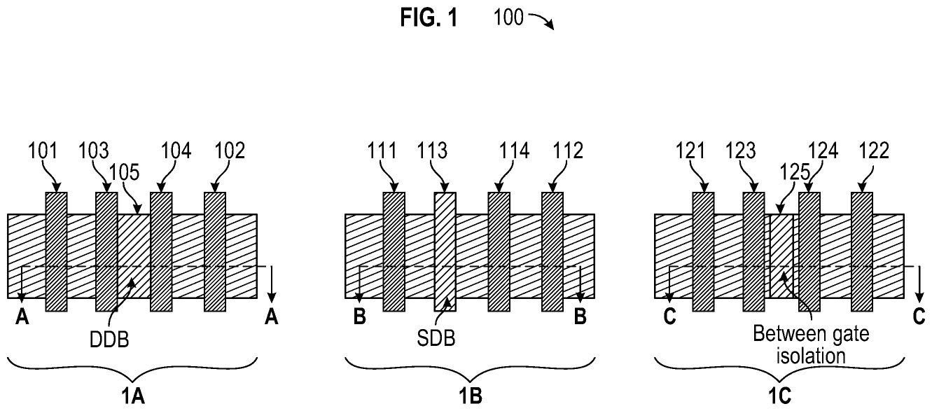

FIG. 1 illustrates a top view 100 of three examples of CMOS isolation techniques. Shown in FIG. 1 are: a double diffusion break (DDB) isolation (labeled as “1A”), a single diffusion break (SDB) isolation (labeled as “1B”) and a between gate isolation (BGI) (labeled as “1C”). Shown in FIG. 1, the view labeled as “1A” shows a top view of DDB isolation with a first transistor gate 101, a second transistor gate 102, a first dummy gate 103, a second dummy gate 104 and a dielectric region 105.

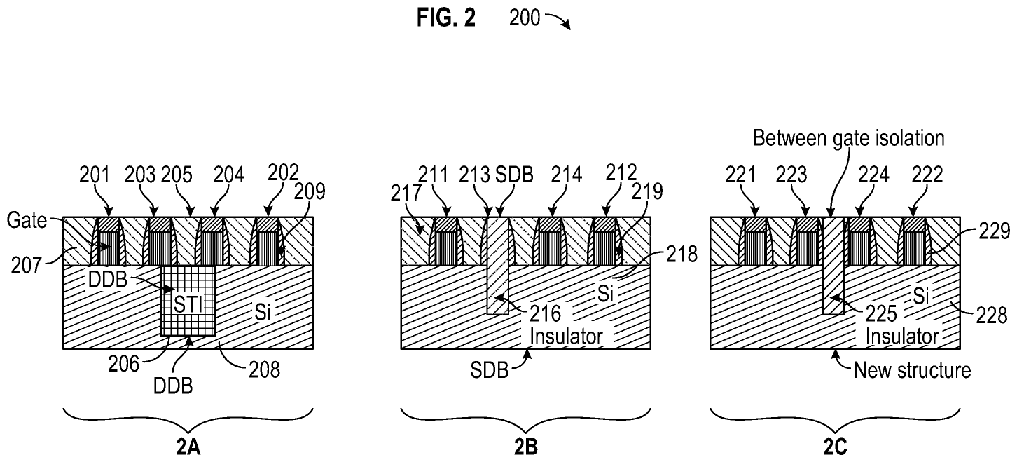

FIG. 2 illustrates a side view 200 of the three examples of CMOS isolation techniques illustrated in FIG. 1. Shown in FIG. 2 are: a DDB isolation (labeled as “2A”), a SDB isolation (labeled as “2B”) and a between gate isolation (labeled as “2C”). Shown in FIG. 2, the view labeled as “2A” shows a side view of DDB isolation with a first transistor gate 201, a second transistor gate 202, a first dummy gate 203, a second dummy gate 204, a first dielectric region 205, a shallow trench isolation (STI) region 206, a second dielectric region 207 (e.g., oxide or a low-K dielectric) and a semiconductor substrate 208 (e.g. silicon substrate). In one example, the STI region 206 is embedded within the semiconductor substrate 208 and its position occupies a region between two gates: the first dummy gate 203 and the second dummy gate 204. In addition, the gates 201, 202, 203, 204 may be surrounded by spacers 209. In one example, the spacers 209 may include silicon nitride (i.e., Si₃N₄). For example, the spacers 209 may be used as an alignment during integrated circuit fabrication.

Shown in FIG. 1, the view labeled as “1B” shows a top view of SDB isolation with a first transistor gate 111, a second transistor gate 112, a first dummy gate 113, and a third transistor gate 114. In one example, the first dummy gate 113 includes an insulator.

Shown in FIG. 2, the view labeled as “2B” shows a side view of SDB isolation with a first transistor gate 211, a second transistor gate 212, a first dummy gate 213, a third transistor gate 214, a dielectric region 217 (e.g., oxide or a low-K dielectric) and a semiconductor substrate 218 (e.g. silicon substrate). In one example, the first dummy gate 213 includes an insulator 216. In one example, the insulator 216 is embedded within the semiconductor substrate 218 and its position occupies a region for one gate: the first dummy gate 213. In addition, the gates 211, 212, 213, 214 may be surrounded by spacers 219. In one example, the spacers 219 may include silicon nitride (i.e., Si₃N₄). For example, the spacers 219 may be used as an alignment during integrated circuit fabrication.

Shown in FIG. 1, the view labeled as “1C” shows a top view of BGI with a first transistor gate 121, a second transistor gate 122, a third transistor gate 123, and a fourth transistor gate 124. In one example, an inter-gate insulator 125 is positioned between the third transistor gate 123 and the fourth transistor gate 124. In one example, the inter-gate insulator 125 provides electrical isolation between adjacent gates, for example, third transistor gate 123 and the fourth transistor gate 124.

Shown in FIG. 2, the view labeled as “2B” shows a side view of BGI with a first transistor gate 221, a second transistor gate 222, a third transistor gate 223, a fourth transistor gate 224 and a semiconductor substrate 228. In one example, an inter-gate insulator 225 is positioned between the third transistor gate 223 and the fourth transistor gate 224. In one example, the inter-gate insulator 225 provides electrical isolation between adjacent gates, for example, third transistor gate 223 and the fourth transistor gate 224. In addition, the gates 221, 222, 223, 224 may be surrounded by spacers 229. In one example, the spacers 229 may include silicon nitride (i.e., Si₃N₄). For example, the spacers 229 may be used as an alignment during integrated circuit fabrication.

For example, various CMOS isolation techniques generate different local stress (i.e., internal force) effects which impact transistor performance differently. In one example, tensile stress is an internal force which may lead to linear expansion in a same direction as the internal force. In one example, carrier mobility is a semiconductor property which describes how fast charge carriers (e.g., electrons or holes) propagate through the semiconductor. For example, carrier mobility may be expressed as a ratio of drift velocity (e.g., in m/s) to applied electric field (e.g., in V/m). For example, DDB isolation generates a tensile stress in a transistor channel which improves NMOS transistor performance (e.g. +11% improvement in NMOS carrier mobility) but degrades PMOS transistor performance (e.g., 8% degradation in PMOS carrier mobility). For example, SDB isolation may have relatively neutral performance impact to tensile stress.

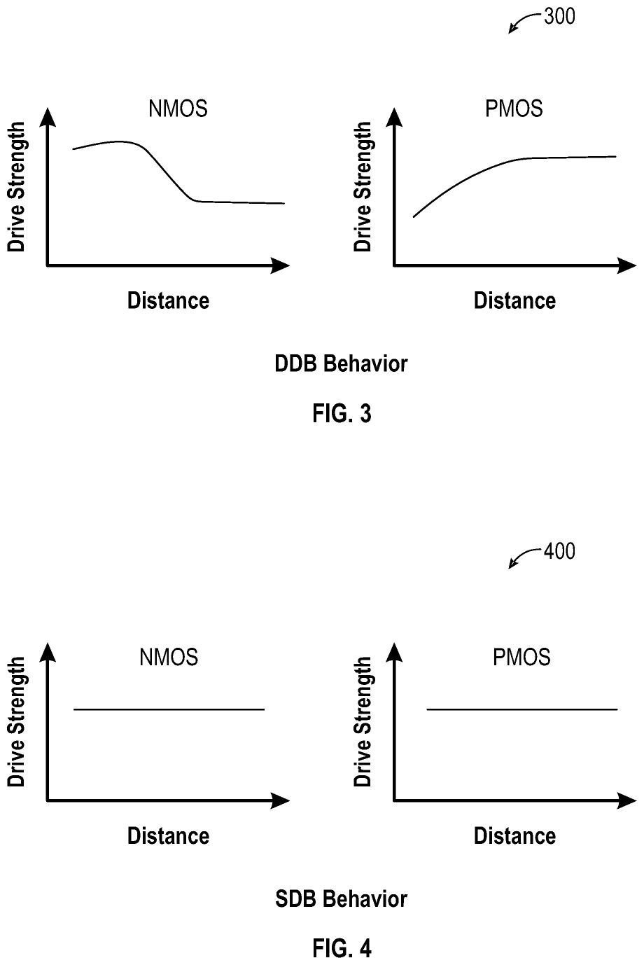

FIG. 3 illustrates an example set of graphs 300 showing the effects of tensile stress on n-type metal oxide semiconductor (NMOS) transistor and p-type metal oxide semiconductor (PMOS) transistor performance for DDB isolation. For example, the two graphs on the left side of FIG. 3 show first voltage Vtsat and drive current Idsat vs. tensile stress (e.g., measured as a linear spacing to a channel in nm) for NMOS transistors. These graphs show, for example, enhanced NMOS carrier mobility as tensile stress increases. For example, the two graphs on the right side of FIG. 3 show second voltage Vtsat and drive current Idsat vs. tensile stress (e.g., measured as a linear spacing to a channel in nm) for PMOS transistors. These graphs show, for example, degraded PMOS carrier mobility as tensile stress increases. Thus, in one example, DDB isolation enhances NMOS carrier mobility and degrades PMOS carrier mobility.

FIG. 4 illustrates an example set of graphs 400 showing the effects of tensile stress on n-type metal oxide semiconductor (NMOS) transistor and p-type metal oxide semiconductor (PMOS) transistor performance for SDB isolation. For example, the two graphs on the left side of FIG. 4 show first voltage Vtsat and drive current Idsat vs. tensile stress (e.g. measured as a linear spacing to a channel in nm) for NMOS transistors. These graphs show, for example, relatively stable NMOS carrier mobility as tensile stress increases. For example, the two graphs on the right side of FIG. 4 show second voltage Vtsat and drive current Idsat vs. tensile stress (e.g. measured as a linear spacing to a channel in nm) for PMOS transistors. These graphs show, for example, relatively stable PMOS carrier mobility as tensile stress increases. Thus, in one example, SDB isolation is relatively neutral to tensile stress.

For example, FIG. 3 and FIG. 4 show that it is possible to use DDB isolation on NMOS transistors only and to use SDB isolation on PMOS transistors only to obtain higher carrier mobility. Conversely, it is possible to use SDB isolation on NMOS transistors only and to use DDB isolation on PMOS transistors only to obtain lower carrier mobility. In one example, various combinations of SDB isolation and DDB isolation on NMOS transistors and PMOS transistors may be used for different carrier mobility characteristics and thus transistor performance. In one example, channel strain can be induced by isolation and device mobility and performance can be influenced. In one example, drive current (Idsat) can be increased or decreased in the range, for example, from 5% to 20% by DDB for PMOS/NMOS. On the other hand, SDB may have lower impact, for example, in the range of 0-5% drive current (Idsat).

In one example, BGI may be implemented on an IC as a simpler fabrication process than SDB and requires no removal of high-K metal gate material. In one example, BGI may use a spacer and gate as a hard mask to etch a substrate (with self-alignment) to form a trench with good selectivity and isolation. In one example, BGI requires no CT mask between shared gates. In one example, BGI dummy gates are conductors and may be used for routing on the IC.

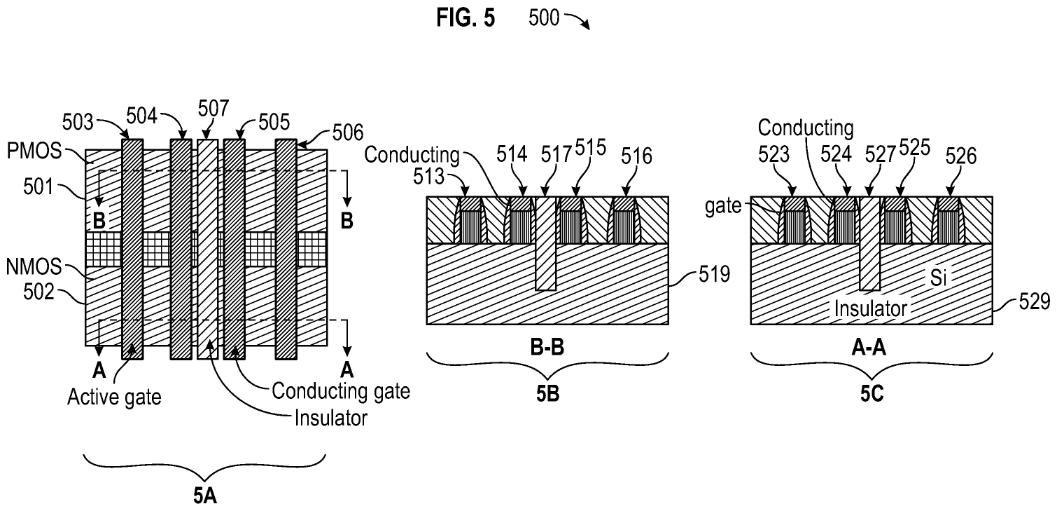

FIG. 5 illustrates a first example 500 of a between gate isolation (BGI) technique. In one example, the first example BGI technique may use between gate isolation (BGI) for both NMOS transistors and PMOS transistors. In FIG. 5, the section labeled as “5A” illustrates a top view for the first example BGI technique with a PMOS section 501 and a NMOS section 502. Also shown are first transistor gate 503, a second transistor gate 504, a third transistor gate 505 and a fourth transistor gate 506. In one example, an insulator 507 is positioned between second transistor gate 504 and third transistor gate 505 to form the BGI.

FIG. 5 in the section labeled as “5B” illustrates a side view for the PMOS section 501 with a first transistor gate 513, a second transistor gate 514, a third transistor gate 515 and a fourth transistor gate 516. Also shown is an insulator 517 positioned between second transistor gate 514 and third transistor gate 515 and into a semiconductor substrate 519 to form the BGI.

FIG. 5 in the section labeled as “5C” illustrates a side view for the NMOS section 502 with a first transistor gate 523, a second transistor gate 524, a third transistor gate 525 and a fourth transistor gate 526. Also shown is an insulator 527 positioned between second transistor gate 524 and third transistor gate 525 and into a semiconductor substrate 529 to form the BGI.

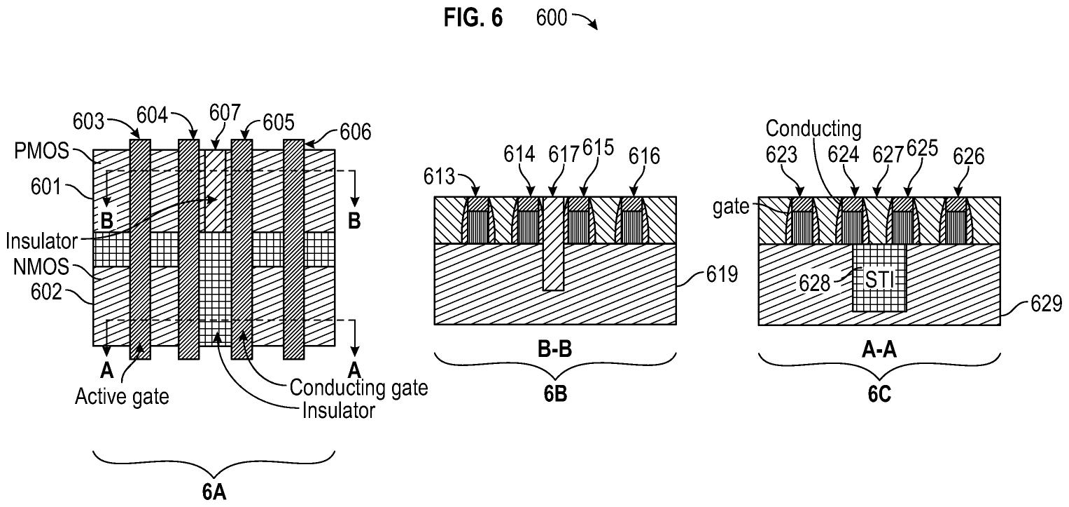

FIG. 6 illustrates a second example 600 of a between gate isolation (BGI) technique. In one example, the second example BGI technique may use between gate isolation (BGI) for PMOS transistors and use DDB isolation for NMOS transistors. FIG. 6A illustrates a top view for the second example BGI technique with a PMOS section 601 using BGI and a NMOS section 602 using DDB isolation. Also shown are first transistor gate 603, a second transistor gate 604, a third transistor gate 606 and a fourth transistor gate 606. In one example, an insulator 607 is positioned between second transistor gate 604 and third transistor gate 606 in the PMOS section 601. In one example, a DDB section 608 is positioned between second transistor gate 604 and third transistor gate 606 in the NMOS section 602.

FIG. 6 in the section labeled as “6B” illustrates a side view for the PMOS section 601 with a first transistor gate 613, a second transistor gate 614, a third transistor gate 616 and a fourth transistor gate 616. Also shown is an insulator 617 positioned between second transistor gate 614 and third transistor gate 616 and into a semiconductor substrate 619 to form the BGI.

FIG. 6 in the section labeled as “6C” illustrates a side view for the NMOS section 602 with a first transistor gate 623, a second transistor gate 624, a third transistor gate 626 and a fourth transistor gate 626. Also shown is an oxide 627 positioned between second transistor gate 624 and third transistor gate 626. Also shown is a STI 628 within a semiconductor substrate 629 and positioned below the oxide 627.

In another example (not shown), the second example BGI technique may use between gate isolation (BGI) for NMOS transistors and use DDB isolation for PMOS transistors. In this example, an insulator is positioned between a second transistor gate and a third transistor gate in the NMOS section to form the BGI. In this example, an oxide is positioned between a second transistor gate and a third transistor gate in the PMOS section, and a STI is positioned below the oxide within a semiconductor substrate in the PMOS section.

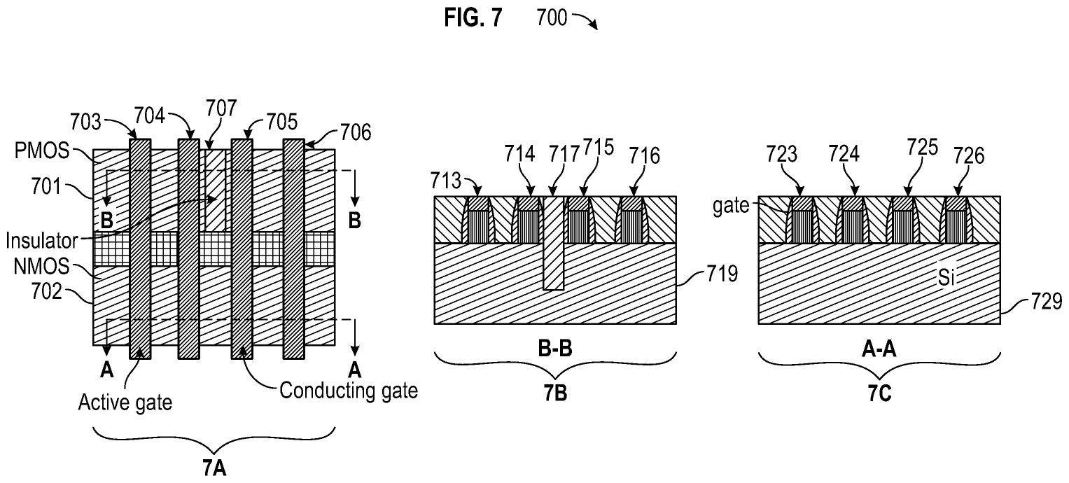

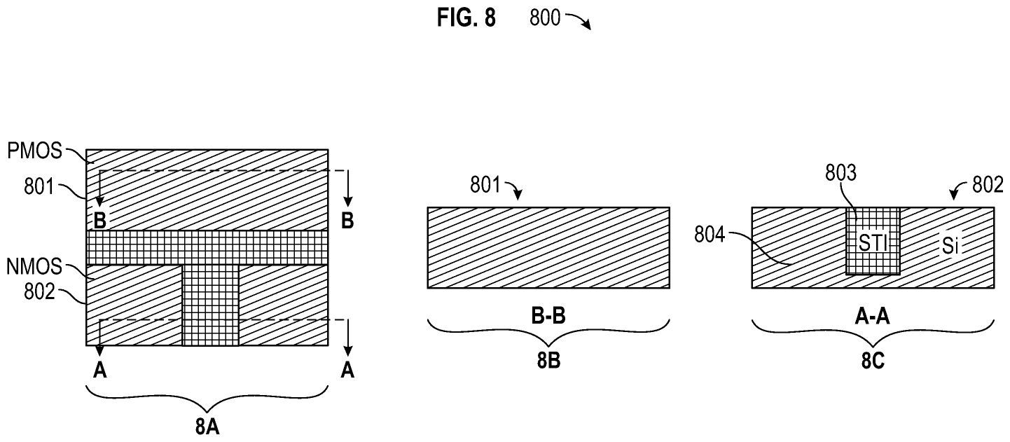

FIG. 7 illustrates a third example 700 of a between gate isolation (BGI) technique. In one example, the third example BGI technique may use between gate isolation (BGI) for PMOS transistors and use no isolation for NMOS transistors. FIG. 7 in the section labeled as “7A” illustrates a top view for the third example BGI technique with a PMOS section 701 using BGI and a NMOS section 702 using no isolation. Also shown are first transistor gate 703, a second transistor gate 704, a third transistor gate 707 and a fourth transistor gate 707. In one example, an insulator 707 is positioned between second transistor gate 704 and third transistor gate 707 in the PMOS section 701 to form the BGI.

FIG. 7 in the section labeled as “7B” illustrates a side view for the PMOS section 701 with a first transistor gate 713, a second transistor gate 714, a third transistor gate 717 and a fourth transistor gate 716. Also shown is an insulator 717 positioned between second transistor gate 714 and third transistor gate 717 and into a semiconductor substrate 719 to form the BGI.

FIG. 7 in the section labeled as “7C” illustrates a side view for the NMOS section 702 with a first transistor gate 723, a second transistor gate 724, a third transistor gate 727 and a fourth transistor gate 726. Also shown is a semiconductor substrate 729 with no isolation.

In another example (not shown), the third example BGI technique may use between gate isolation (BGI) for NMOS transistors and use no isolation for PMOS transistors. In this example, an insulator is positioned between a second transistor gate and a third transistor gate in the NMOS section to form the BGI. In this example, no isolation is used in the PMOS section.

FIG. 8 illustrates a first process implementation step 800 for BGI isolation in an integrated circuit to form a shallow trench isolation (STI) in a semiconductor substrate with etching and filling of oxide. FIG. 8 in the section labeled as “8A” shows a top view with a PMOS section 801 and a NMOS section 802. FIG. 8 in the section labeled as “8B” illustrates a side view for the PMOS section 801. FIG. 8 in the section labeled as “8C” illustrates a side view for the NMOS section 802. In one example, the first process step places a STI 803 into semiconductor substrate 804 (e.g., silicon substrate) in NMOS section 802.

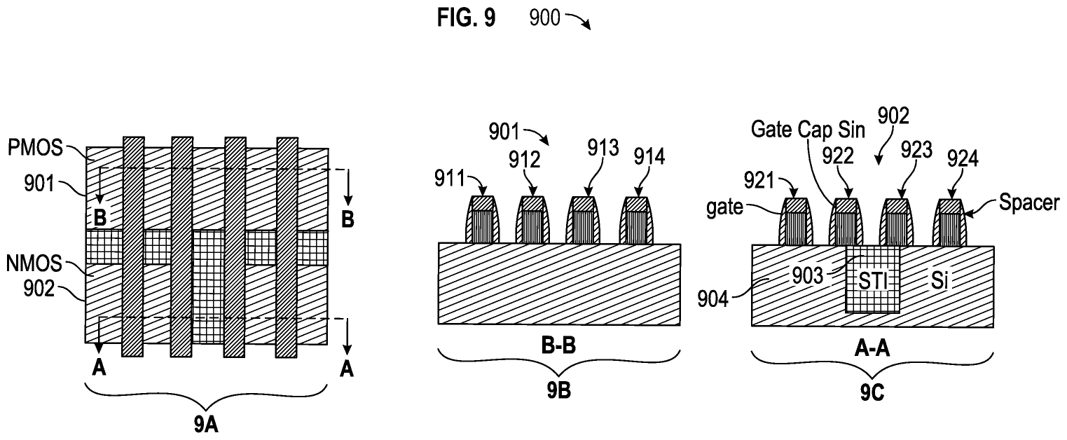

FIG. 9 illustrates a second process implementation step 900 for BGI isolation in an integrated circuit to form gates and spacers. FIG. 9 in the section labeled as “9A” shows a top view with a PMOS section 901 and a NMOS section 902. FIG. 9 in the section labeled as “9B” illustrates a side view for the PMOS section 901. In one example, the second process step places a plurality of gates 911, 912, 913, 914 in PMOS section 901. In one example, each gate in PMOS section 901 may include a polysilicon gate, a replacement metal gate, a gate insulator, etc. FIG. 9 in the section labeled as “9C” illustrates a side view for the NMOS section 902. In one example, the second process step places a plurality of gates 921, 922, 923, 924 in NMOS section 902. In one example, each gate in NMOS section 902 may include a polysilicon gate, a replacement metal gate, a gate insulator, etc.

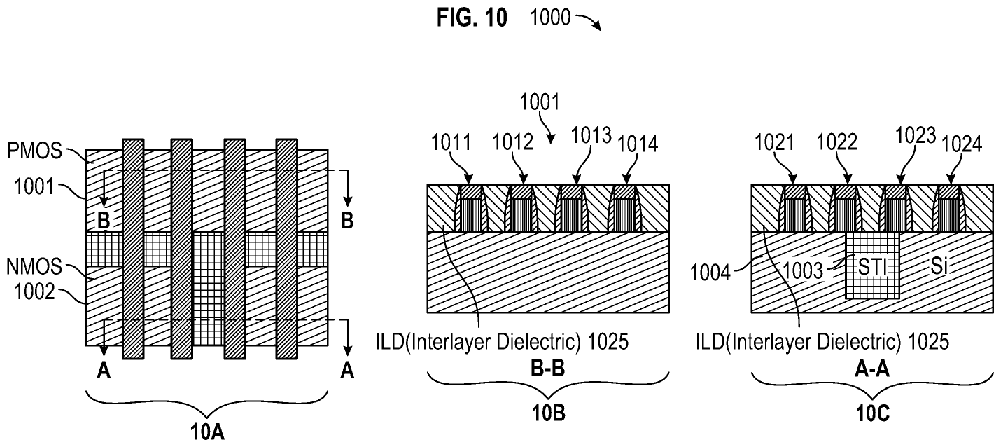

FIG. 10 illustrates a third process implementation step 1000 for BGI isolation in an integrated circuit to deposit an interlayer dielectric (ILD) and to planarize the integrated circuit. FIG. 10 in the section labeled as “10A” shows a top view with a PMOS section 1001 and a NMOS section 1002. FIG. 10 in the section labeled as “10B” illustrates a side view for the PMOS section 1001. In one example, the third process step places a first interlayer dielectric (ILD) 1015 which surrounds a first plurality of gates 1011, 1012, 1013, 1014 in PMOS section 1001. FIG. 10 in the section labeled as “10C” illustrates a side view for the NMOS section 1002. For example, NMOS section 1002 includes STI 1003 and semiconductor substrate 1004. In one example, the third process step places a second interlayer dielectric (ILD) 1025 which surrounds a second plurality of gates 1021, 1022, 1023, 1024 in NMOS section 1002. In one example, the third process step planarizes the IC by removing excess ILD above the first and second plurality of gates.

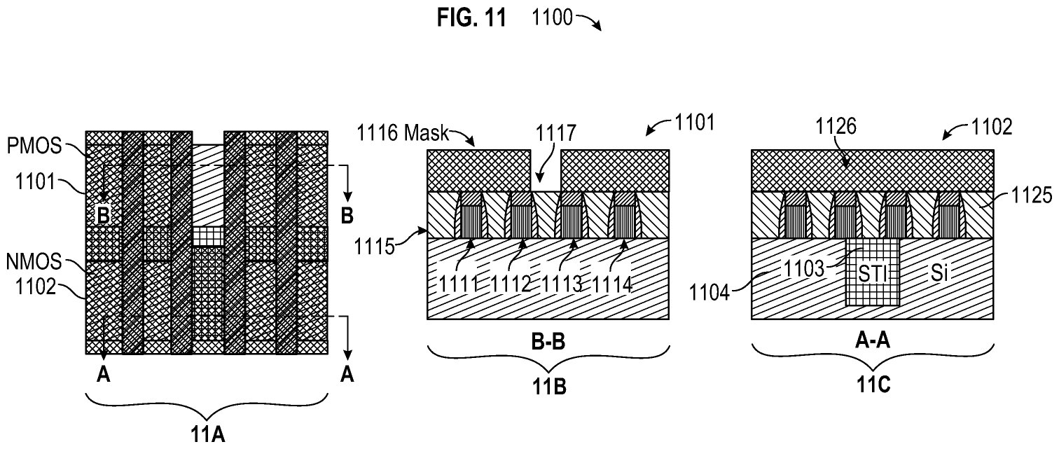

FIG. 11 illustrates a fourth process implementation step 1100 for BGI isolation in an integrated circuit to form a mask and to expose a diffusion break region. FIG. 11 in the section labeled as “11A” shows a top view with a PMOS section 1101 and a NMOS section 1102. FIG. 11 in the section labeled as “11B” illustrates a side view for the PMOS section 1101. In one example, the PMOS section 1101 includes gates 1111, 1112, 1113, 1114. In one example, the fourth process step forms a first mask 1116 above first ILD 1115 in the PMOS section 1101. In one example, the first mask 1116 includes a gap 1117 (i.e., an opening) between gate 1112 and gate 1113. In one example, the gap 1117 exposes a diffusion break region in the PMOS section 1101. FIG. 11 in the section labeled as “11C” illustrates a side view for the NMOS section 1102. For example, NMOS section 1102 includes STI 1103 and semiconductor substrate 1104. In one example, the fourth process step forms a second mask 1126 above second ILD 1125 in the NMOS section 1102.

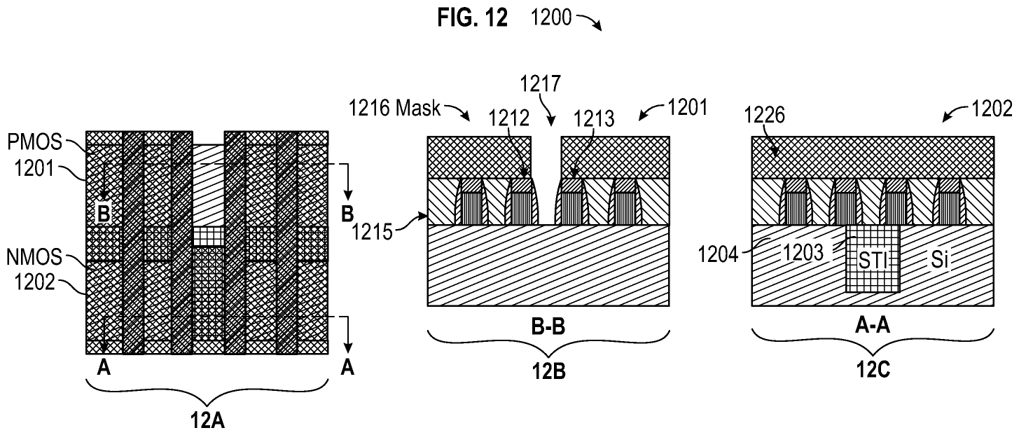

FIG. 12 illustrates a fifth process implementation step 1200 for BGI isolation in an integrated circuit to etch the ILD between two gates in a PMOS section 1201. FIG. 12 in the section labeled as “12A” shows a top view with the PMOS section 1201 and a NMOS section 1202. FIG. 12 in the section labeled as “12B” illustrates a side view for the PMOS section 1201. In one example, the fifth process step etches (i.e., removes) ILD between two gates (for example, gate 1212 and gate 1213) in PMOS section 1201. In one example, the etching ILD 1215 is performed within a gap 1217 in first mask 1216. FIG. 12 in the section labeled as “12C” illustrates a side view for the NMOS section 1202. For example, NMOS section 1202 includes STI 1203 and semiconductor substrate 1204.

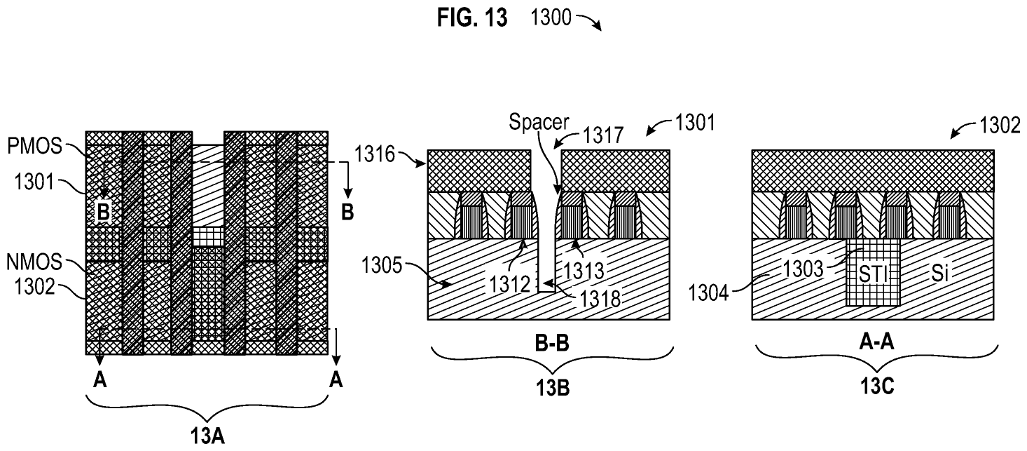

FIG. 13 illustrates a sixth process implementation step 1300 for BGI isolation in an integrated circuit to etch the semiconductor substrate to form a trench within an active region self-aligned to gates with spacers in PMOS section 1301. FIG. 13 in the section labeled as “13A” shows a top view with the PMOS section 1301 and a NMOS section 1302. FIG. 13 in the section labeled as “13B” illustrates a side view for the PMOS section 1301. In one example, the sixth process step etches (i.e., removes) an active region to form a trench 1318 in semiconductor substrate 1305 between two gates (for example, gate 1312 and gate 1313) in PMOS section 1301. In one example, the etching to form trench 1318 is performed within a gap 1317 in first mask 1316. FIG. 13 in the section labeled as “13C” illustrates a side view for the NMOS section 1302. For example, NMOS section 1302 includes STI 1303 and semiconductor substrate 1304.

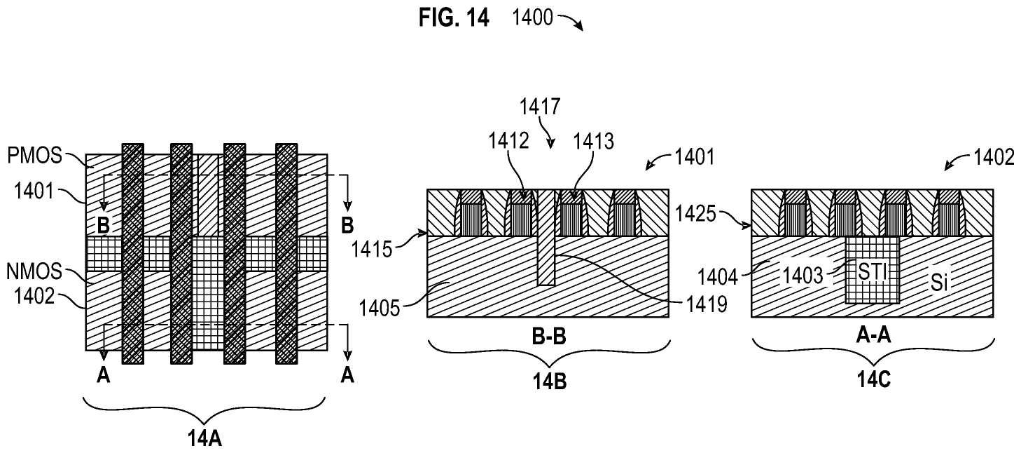

FIG. 14 illustrates a seventh process implementation step 1400 for BGI isolation in an integrated circuit to fill the trench with insulator in PMOS section 1401 and to planarize the integrated circuit. FIG. 14 in the section labeled as “14A” shows a top view with the PMOS section 1401 and a NMOS section 1402. FIG. 14 in the section labeled as “14B” illustrates a side view for the PMOS section 1401. In one example, the seventh process step fills the trench 1418 and a gap 1417 (between gate 1412 and gate 1413) with an insulator 1419. In one example, the gap 1417 is positioned above the trench 1418, and the trench 1418 is in semiconductor substrate 1405. FIG. 14 in the section labeled as “14C” illustrates a side view for the NMOS section 1402. For example, NMOS section 1402 includes STI 1403 and semiconductor substrate 1404. In one example, the seventh process step planarizes the integrated circuit by removing the first mask above the first ILD 1415 and the second mask above the second ILD 1425.

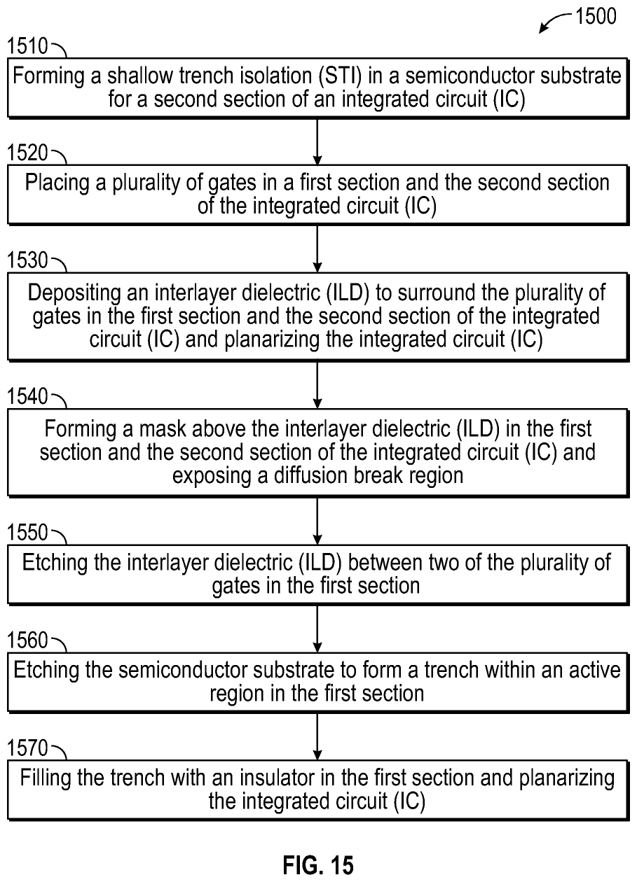

FIG. 15 illustrates a first process flow 1500 for implementing between gate isolation (BGI) in an integrated circuit with a first section and a second section. In one example, the first process flow 1500 is for implementing between gate isolation (BGI) in an integrated circuit with a first section and a second section in a CMOS integrated circuit. In block 1510, form a shallow trench isolation (STI) in a semiconductor substrate for a second section of an integrated circuit (IC). In one example, the first section is a PMOS section and the second section is a NMOS section. In another example, the first section is a NMOS section and the second section is a PMOS section.

In block 1520, place a plurality of gates in a first section and the second section of the integrated circuit (IC). In one example, the first section and the second section are adjacent. In one example, the plurality of gates includes a polysilicon gate, a replacement metal gate and gate insulator. In one example, the plurality of gates is surrounded by spacers. In one example, the first section is a PMOS section and the second section is a NMOS section. In another example, the first section is a NMOS section and the second section is a PMOS section.

In block 1530, deposit an interlayer dielectric (ILD) to surround the plurality of gates in the first section and the second section of the integrated circuit (IC) and planarize the integrated circuit (IC). In one example, the ILD is an oxide material. In one example, planarizing includes removing excess ILD above the plurality of gates. In one example, the first section is a PMOS section and the second section is a NMOS section. In another example, the first section is a NMOS section and the second section is a PMOS section.

In block 1540, form a mask above the interlayer dielectric (ILD) in the first section and the second section of the integrated circuit (IC) and expose a diffusion break region. In one example, the diffusion break region is over the first section only. In one example, the first section is a PMOS section and the second section is a NMOS section. In another example, the first section is a NMOS section and the second section is a PMOS section.

In block 1550, etch the interlayer dielectric (ILD) between two of the plurality of gates in the first section. In one example, the first section is a PMOS section. In another example, the first section is a NMOS section.

In block 1560, etch the semiconductor substrate to form a trench within an active region in the first section. In one example, the first section is a PMOS section. In another example, the first section is a NMOS section.

In block 1570, fill the trench with an insulator in the first section and planarize the integrated circuit (IC). In one example, the planarizing includes removing the mask above the ILD in the first section and the second section. In one example, the first section is a PMOS section and the second section is a NMOS section. In another example, the first section is a NMOS section and the second section is a PMOS section.

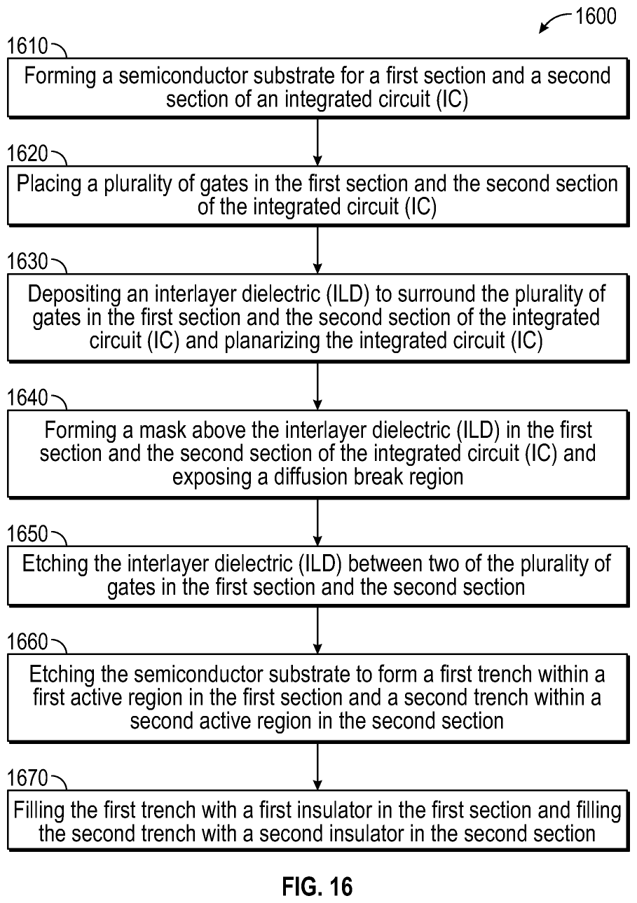

FIG. 16 illustrates a second process flow 1600 for implementing between gate isolation (BGI) in an integrated circuit with a first section and a second section. In one example, the second process flow 1600 is for implementing between gate isolation (BGI) in an integrated circuit with a first section and a second section in a CMOS integrated circuit. In block 1610 form a semiconductor substrate for a first section and a second section of an integrated circuit (IC). In one example, the first section is a PMOS section and the second section is a NMOS section. In another example, the first section is a NMOS section and the second section is a PMOS section.

In block 1620, place a plurality of gates in the first section and the second section of the integrated circuit (IC). In one example, the first section and the second section are adjacent. In one example, the plurality of gates includes a polysilicon gate, a replacement metal gate and gate insulator. In one example, the plurality of gates is surrounded by spacers. In one example, the first section is a PMOS section and the second section is a NMOS section. In another example, the first section is a NMOS section and the second section is a PMOS section.

In block 1630, deposit an interlayer dielectric (ILD) to surround the plurality of gates in the first section and the second section of the integrated circuit (IC) and planarize the integrated circuit (IC). In one example, the ILD is an oxide material. In one example, planarizing includes removing excess ILD above the plurality of gates. In one example, the first section is a PMOS section and the second section is a NMOS section. In another example, the first section is a NMOS section and the second section is a PMOS section.

In block 1640, form a mask above the interlayer dielectric (ILD) in the first section and the second section of the integrated circuit (IC) and expose a diffusion break region. In one example, the diffusion break region is over both the first section and the second section. In one example, the first section is a PMOS section and the second section is a NMOS section. In another example, the first section is a NMOS section and the second section is a PMOS section.

In block 1650, etch the interlayer dielectric (ILD) between two of the plurality of gates in the first section and the second section. In one example, the first section is a PMOS section and the second section is a NMOS section. In another example, the first section is a NMOS section and the second section is a PMOS section.

In block 1660, etch the semiconductor substrate to form a first trench within a first active region in the first section and a second trench within a second active region in the second section. In one example, the first section is a PMOS section. In another example, the first section is a NMOS section.

In block 1670, fill the first trench with a first insulator in the first section and fill the second trench with a second insulator in the second section. In one example, the planarizing includes removing the mask above the ILD in the first section and the second section. In one example, the first section is a PMOS section and the second section is a NMOS section. In another example, the first section is a NMOS section and the second section is a PMOS section.

In one aspect, one or more of the steps for providing complementary metal oxide semiconductor (CMOS) isolation in FIGS. 15 and 16 may be executed by one or more processors which may include hardware, software, firmware, etc. In one aspect, one or more of the steps in FIGS. 15 and 16 may be executed by one or more processors which may include hardware, software, firmware, etc. The one or more processors, for example, may be used to execute software or firmware needed to perform the steps in the flow diagrams of FIGS. 15 and 16. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in the processing system, external to the processing system, or distributed across multiple entities including the processing system. The computer-readable medium may be embodied in a computer program product. By way of example, a computer program product may include a computer-readable medium in packaging materials. The computer-readable medium may include software or firmware for complementary metal oxide semiconductor (CMOS) isolation. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. A method for implementing a complementary metal oxide semiconductor (CMOS) isolation, the method comprising:
etching an interlayer dielectric (ILD) between two of a plurality of gates in a first section of an integrated circuit (IC);
etching a semiconductor substrate to form a trench within an active region in the first section; and
filling the trench with an insulator in the first section and planarizing the integrated circuit (IC).

2. The method of claim 1, further comprising forming a shallow trench isolation (STI) in the semiconductor substrate for a second section of the integrated circuit (IC).

3. The method of claim 2, wherein the first section is a p-type metal oxide semiconductor (PMOS) section and the second section is a n-type metal oxide semiconductor (NMOS) section.

4. The method of claim 2, wherein the first section is a n-type metal oxide semiconductor (NMOS) section and the second section is a p-type metal oxide semiconductor (PMOS) section.

5. The method of claim 2, further comprising placing the plurality of gates in the first section and in the second section of the integrated circuit (IC).

6. The method of claim 5, wherein the first section and the second section are adjacent.

7. The method of claim 6, further comprising depositing an interlayer dielectric (ILD) to surround the plurality of gates in the first section and in the second section of the integrated circuit (IC) and planarizing the integrated circuit (IC).

8. The method of claim 7, wherein the interlayer dielectric (ILD) is an oxide material.

9. The method of claim 7, wherein the planarizing includes removing excess interlayer dielectric (ILD) above the plurality of gates.

10. The method of claim 7, further comprising forming a mask above the interlayer dielectric (ILD) in the first section and in the second section of the integrated circuit (IC) and exposing a diffusion break region.

11. The method of claim 10, wherein the planarizing includes removing the mask above the interlayer dielectric (ILD) in the first section and the second section.

12. The method of claim 10, wherein the diffusion break region is over the first section only.

13. The method of claim 1, wherein the plurality of gates includes a polysilicon gate, a replacement metal gate and gate insulator.

14. The method of claim 1, wherein the plurality of gates is surrounded by at least one spacer.

15. A method for implementing a complementary metal oxide semiconductor (CMOS) isolation, the method comprising:
etching an interlayer dielectric (ILD) between two of a plurality of gates in a first section and a second section of an integrated circuit (IC);
etching a semiconductor substrate to form a first trench within a first active region in the first section and a second trench within a second active region in the second section; and
filling the first trench with a first insulator in the first section and filling the second trench with a second insulator in the second section and planarizing the integrated circuit (IC).

16. The method of claim 15, wherein the planarizing includes removing a mask above the interlayer dielectric (ILD) in the first section and the second section.

17. The method of claim 15, wherein the first section is a p-type metal oxide semiconductor (PMOS) section and the second section is a n-type metal oxide semiconductor (NMOS) section.

18. The method of claim 15, wherein the first section is a n-type metal oxide semiconductor (NMOS) section and the second section is a p-type metal oxide semiconductor (PMOS) section.

19. The method of claim 15, wherein the plurality of gates includes a polysilicon gate, a replacement metal gate and gate insulator.

20. The method of claim 15, wherein the plurality of gates is surrounded by at least one spacer.

21. The method of claim 15, further comprising forming a semiconductor substrate for the first section and the second section of the integrated circuit (IC).

22. The method of claim 21, further comprising placing the plurality of gates in the first section and the second section of the integrated circuit (IC).

23. The method of claim 21, further comprising depositing the interlayer dielectric (ILD) to surround the plurality of gates in the first section and the second section of the integrated circuit (IC).

24. The method of claim 23, further comprising forming a mask above the interlayer dielectric (ILD) in the first section and the second section of the integrated circuit (IC) and exposing a diffusion break region.

25. The method of claim 24, wherein the diffusion break region is over both the first section and the second section.

26. An apparatus with complementary metal oxide semiconductor (CMOS) isolation, the apparatus comprising:
a semiconductor substrate;
a first pair of transistors coupled to the semiconductor substrate, wherein a first of the first pair of transistors includes a first gate and a second of the first pair of transistors includes a second gate; and
a first insulator positioned between the first gate and the second gate, wherein the first insulator extends through the semiconductor substrate.

27. The apparatus of claim 26, further comprising:
a second pair of transistors coupled to the semiconductor substrate, wherein a first of the second pair of transistors includes a third gate and a second of the second pair of transistors includes a fourth gate; and
a second insulator positioned between the third gate and the fourth gate, wherein the second insulator extends through the semiconductor substrate, and wherein the second pair of transistors is a pair of p-type metal oxide semiconductor (PMOS) transistors and the first pair of transistors is a pair of n-type metal oxide semiconductor (NMOS) transistors.

28. A computer-readable medium storing computer executable code, operable on a device comprising at least one processor and at least one memory coupled to the at least one processor, wherein the at least one processor is configured to implement complementary metal oxide semiconductor (CMOS) isolation, the computer executable code comprising:
instructions for causing a computer to etch an interlayer dielectric (ILD) between two of a plurality of gates in a first section of an integrated circuit (IC);
instructions for causing the computer to etch a semiconductor substrate to form a trench within an active region in the first section; and
instructions for causing the computer to fill the trench with an insulator in the first section and to planarize the integrated circuit (IC).

29. The computer-readable medium of claim 28, further comprising instructions for causing the computer to form a shallow trench isolation (STI) in the semiconductor substrate for a second section of an integrated circuit (IC).

30. The computer-readable medium of claim 29, further comprising instructions for causing the computer to deposit an interlayer dielectric (ILD) to surround the plurality of gates in the first section and in the second section of the integrated circuit (IC), to planarize the integrated circuit (IC), to form a mask above the interlayer dielectric (ILD) in the first section and in the second section of the integrated circuit (IC), and to expose a diffusion break region.
